(19) United States
(12) Patent Application Publication
(10) Pub. No.: US 2025/0338702 A1
(43) Pub. Date: Oct. 30, 2025

(54) MICRO LED DISPLAY PANEL AND INTEGRATED CIRCUIT BACKPLANE

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN); Qunchao XU, Shanghai (CN)

(21) Appl. No.: 19/190,555

(22) Filed: Apr. 25, 2025

(30) Foreign Application Priority Data
Apr. 26, 2024 (WO) PCT/CN2024/090051

(51) Int. Cl. H10H 29/85; H01L 25/075

(52) U.S. Cl. CPC H10H 29/8585; H01L 25/0753; H10H 29/857; H10H 29/8581; H10H 29/8583

(57) ABSTRACT

A micro LED display panel includes an integrated circuit (IC) backplane including a bottom pad array and a micro LED array comprising a plurality of micro LED structures provided on the IC backplane, one micro LED structure of the plurality of micro LED structures being electrically connected with one bottom pad of the plurality of bottom pads. The micro LED structure includes a mesa structure; a first thermal conductive layer formed surrounding a sidewall of the mesa structure, a material of the first thermal conductive layer being an electrically insulative material with high thermal conductivity; and a second thermal conductive layer filled between adjacent ones of micro LED structures. The IC backplane further includes: one or more heat dissipation structures provided corresponding to an area outside the micro LED structure and passing thought the IC backplane to radiate heat to outside, wherein the heat dissipation structure and the bottom pad are separated.

### CROSS-REFERENCE TO RELATED APPLICATIONS

The present disclosure claims the benefits of priority to PCT Application No. PCT/CN 2024/090051, filed on Apr. 26, 2024, which is incorporated herein by reference in its entirety.

### TECHNICAL FIELD

The present disclosure generally relates to micro LED manufacturing technology, and more particularly, to a micro LED display panel and an integrated circuit (IC) backplane.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

Generally, a micro LED display panel includes an array of micro LEDs. Each micro LED may generate heat when emitting light. However, high temperature may impact the performance of the micro LED display panel. Therefore, there is a challenge to improve a heat dissipation effect.

### SUMMARY OF THE DISCLOSURE

Embodiments of the present disclosure provide a micro LED display panel. The micro LED display panel includes an integrated circuit (IC) backplane including a bottom pad array, the bottom pad array including a plurality of bottom pads; and micro LED array including a plurality of micro LED structures provided on the IC backplane, one micro LED structure of the plurality of micro LED structures being electrically connected with one bottom pad of the plurality of bottom pads. Each of the micro LED structures includes a mesa structure; a first thermal conductive layer formed surrounding a sidewall of the mesa structure, a material of the first thermal conductive layer being an electrically insulative material with high thermal conductivity; and a second thermal conductive layer filled between adjacent ones of micro LED structures, a material of the second thermal conductive layer being a material with high thermal conductivity. The IC backplane includes one or more heat dissipation structures corresponding to an area outside the micro LED structure and passing thought the IC backplane to radiate heat to outside, wherein the heat dissipation structure and the bottom pad are separated.

Embodiments of the present disclosure also provide an integrated circuit (IC) backplane. The IC backplane includes a plurality of bottom pad, one bottom pad of the plurality of bottom pads being electrically connected with one micro LED structure of a plurality of micro LED structures; and one or more heat dissipation structures provided corresponding to an area outside the micro LED structure and passing thought the IC backplane to radiate heat to outside, wherein the heat dissipation structure and the bottom pad are separated.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural cross-sectional diagram of an exemplary micro LED display panel, according to some embodiments of the present disclosure.

FIG. 2 illustrates a structural cross-sectional diagram of another exemplary micro LED display panel, according to some embodiments of the present disclosure.

FIG. 3 illustrates a structural cross-sectional diagram of another exemplary micro LED display panel, according to some embodiments of the present disclosure.

FIG. 4 illustrates a structural cross-sectional diagram of another exemplary micro LED display panel, according to some embodiments of the present disclosure.

FIG. 5 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED display panel having improved heat dissipation efficiency.

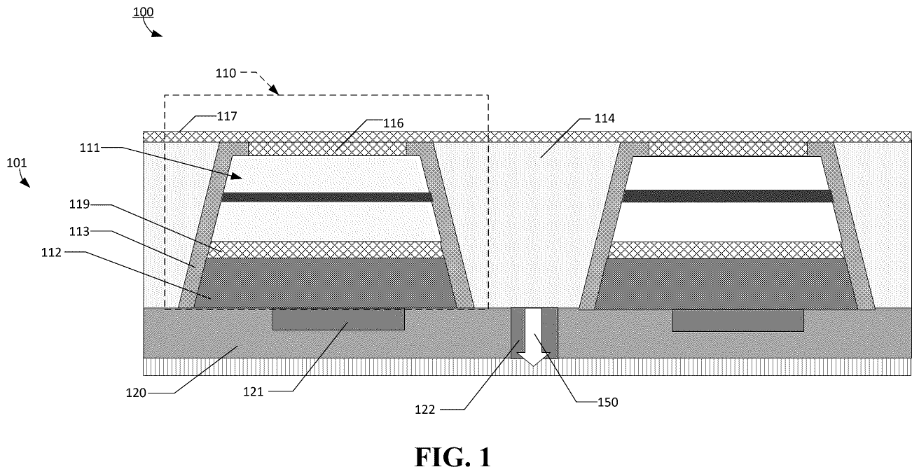

FIG. 1 illustrates a structural cross-sectional diagram of an exemplary micro LED display panel 100, according to some embodiments of the present disclosure. Micro LED display panel 100 includes a micro LED array 101 and an IC (integrated circuit) backplane 120. Micro LED array 101 is located on IC backplane 120 to form an image display area of micro LED display panel 100. Micro LED array 101 includes a plurality of micro LED structures 110. FIG. 1 shows two complete micro LED structures 110, and only one micro LED structure 110 is described for illustrative purposes. Accordingly, it can be understood that micro LED array 101 may include a plurality of micro LED structures 110. Referring to FIG. 1 micro LED structure 110 includes a mesa structure 111 and a bottom bonding layer 112. Bottom bonding layer 112 is provided at a bottom of mesa structure 111 to connect mesa structure 111 with a bottom pad 121 of integrated circuit (IC) backplane 120. IC backplane 120 is provided at a bottom of micro LED array 101 for providing control of micro LED array 101. One micro LED structure 110 of the plurality of micro LED structures is electrically connected with one bottom pad 121 of the plurality of bottom pads.

Micro LED structure 110 further includes a first thermal conductive layer 113 formed surrounding a sidewall of mesa structure 111. A material of first thermal conductive layer 113 is an electrically insulative material with high thermal conductivity, so that first thermal conductive layer 113 can radiate heat generated by mesa structure 111. In some embodiments, a thermal conductivity of the electrically insulative material of first thermal conductive layer 113 is greater than 300 W/mK. For example, the material of first thermal conductive layer 113 is AlN, SiC, Boron, Nitride, diamond, diamond-like carbon, and the like.

In some embodiments, micro LED array 101 further includes a second thermal conductive layer 114 filled between adjacent ones of micro LED structures 110. A material of second thermal conductive layer 114 is a material with high thermal conductivity, so that second thermal conductive layer 114 can further radiate the heat to the air. For example, a thermal conductivity of the material of second thermal conductive layer 114 is greater than 300 W/mK. In some embodiments, the material of second thermal conductive layer 114 is electrically insulative. For example, AlN, SiC, Boron, Nitride, diamond, diamond-like carbon, and the like. In some embodiments, the material of second thermal conductive layer 114 is electrically conductive, for example, Ag, Cu, Al, Graphite, or Graphene. In some embodiments, a material of first thermal conductive layer 113 and a material of second thermal conductive layer 114 can be the same or different.

Referring to FIG. 1, IC backplane 120 further includes one or more heat dissipation structures 122 provided corresponding to an area outside micro LED structure 110 and passing through IC backplane 120 to radiate heat to outside, shown as an arrow 150 in FIG. 1 As shown in FIG. 1 when micro LED display panel 100 is provided in a horizontal direction, that is the light emits in a vertical direction, one or more heat dissipation structures 122 passes through IC backplane 120 in the vertical direction. Heat dissipation structure 122 and bottom pad 121 are separated. With heat dissipation structure 122, the heat dissipation efficiency can be further improved. In this example, as shown in FIG. 1, heat dissipation structure 122 is in contact with second thermal conductive layer 114 to radiate the heat from second thermal conductive layer 114.

In some embodiments, the one or more heat dissipation structures 122 are provided corresponding to areas between adjacent ones of micro LED structures 110. In some embodiments, the one or more heat dissipation structures 122 are provided at an edge of micro LED display panel 100.

In some embodiments, a material of dissipation structure 122 is a metal. In some embodiments, a material of dissipation structure 122 and a material of bottom pad 121 are the same. For example, heat dissipation structure 122 is a Cu pad.

In some embodiments, as shown in FIG. 1, first thermal conductive layer 113 is further provided on a portion of a top surface of mesa structure 111 and forms an opening on the top surface of mesa structure 111. A first top conductive layer 116 is further provided to fill the opening. In some embodiments, first top conductive layer 116 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, as shown in FIG. 1 micro LED array 101 further includes a second top conductive layer 117 provided on a top of micro LED structure 110, and respective first top conductive layers 116 of the plurality of micro LED structure are interconnected to form a whole conductive layer. In some embodiments, second top conductive layer 117 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like. A material of first top conductive layer 116 and a material of second top conductive layer can be the same or different.

In some embodiments, micro LED structure 110 further includes a bottom conductive layer 119 provided between mesa structure 111 and bonding layer 112 to provide an ohmic contact between mesa structure 111 and bonding layer 112. In some embodiments, bottom conductive layer 119 includes an omni-directional reflector (ODR) structure with high reflectivity. In some embodiments, bottom conductive layer 119 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, mesa structure 111 includes a P-N structure. For example, mesa structure 111 includes a first semiconductor layer, a second semiconductor layer, and a light emitting layer provided between the first semiconductor layer and the second semiconductor layer. The first semiconductor layer is provided on the light emitting layer, and the light emitting layer is provided on the second semiconductor layer. Bonding layer 112 is provided at a bottom surface of the second semiconductor layer. The light emitting layer can emit red light, green light, or blue light. In some embodiments, an area of a top surface of mesa structure 111 is smaller than an area of bottom surface of mesa structure 111. In some embodiments, the first semiconductor layer is an N-type semiconductor layer, and the second semiconductor layer is a P-type semiconductor layer.

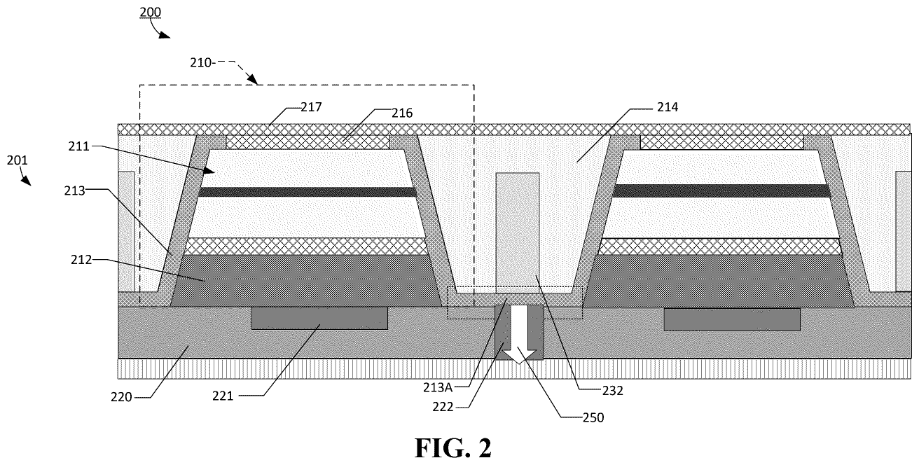

FIG. 2 illustrates a structural cross-sectional diagram of another exemplary micro LED display panel 200, according to some embodiments of the present disclosure. FIG. 2 shows two complete micro LED structures 210, and only micro LED structure 210 is described for illustrative purposes. Accordingly, it can be understood that micro LED display panel 200 may include a plurality of micro LED structures 210. Referring to FIG. 2 similar to micro LED array 100 shown in FIG. 1 micro LED structure 210 includes a mesa structure 211 and a bonding layer 212. Bonding layer 212 is provided at a bottom of mesa structure 211 to bond mesa structure 211 with an integrated circuit (IC) backplane 220. Micro LED structure 210 further includes a first thermal conductive layer 213 formed surrounding sidewalls of mesa structure 211 and bonding layer 212. In this example, first thermal conductive layer 213 is further formed on a top surface of IC backplane 220 between adjacent ones of micro LED structures 210. For example, first thermal conductive layer 213 includes a portion 213A provided on IC backplane 220 between adjacent ones of micro LED structures 210. Accordingly, first thermal conductive layer 213 is continuously formed in this example, and can further radiate heat from IC backplane 220.

IC backplane 220 further includes one or more heat dissipation structures 222 provided corresponding to an area outside micro LED structure 210 and passing thought IC backplane 220 to radiate heat to outside, shown as an arrow 250 in FIG. 2 Heat dissipation structure 222 and bottom pad 221 are separated. In this example, as shown in FIG. 2, heat dissipation structure 222 is in contact with first thermal conductive layer 213 to radiate the heat from first thermal conductive layer 213.

As shown in FIG. 2 micro LED display panel 200 further includes a second thermal conductive layer 214 filled between adjacent ones of micro LED structures 210. In some embodiments, micro LED array 201 further includes an isolation structure 232 provided between adjacent ones of micro LED structures 210 to isolate light and reduce cross talk between the adjacent ones of micro LED structures 210. In some embodiments, the material of second thermal conductive layer 214 is electrically insulative. A material of isolation structure 232 can be electrically conductive or electrically insulative. In some embodiments, when the material of second thermal conductive layer 214 is electrically conductive, a material of isolation structure 232 is electrically insulative.

Referring to FIG. 2 micro LED array 201 further includes a second top conductive layer 217 provided on a top of micro LED structure 210, and respective top conductive layers 216 of the plurality of micro LED structure are interconnected to form a whole conductive layer.

Description of other features of micro LED display panel 200 may be found by referring to such features described above with reference to FIG. 1 which will not be repeated here.

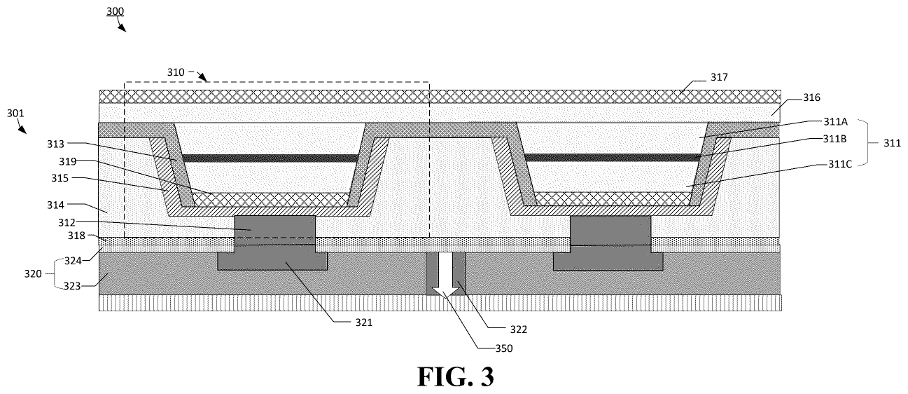

FIG. 3 illustrates a structural cross-sectional diagram of an exemplary micro LED display panel 300, according to some embodiments of the present disclosure. Micro LED display panel 300 includes a micro LED array 301 and an IC (integrated circuit) backplane 320. Micro LED array 301 is located on an IC backplane 320 to form an image display area of micro LED display panel 300. Micro LED array 301 includes a plurality of micro LED structures 310. FIG. 1 shows two complete micro LED structures 310, and only micro LED structure 310 is described for illustrative purposes. Accordingly, it can be understood that micro LED array 301 may include a plurality of micro LED structures 310. Referring to FIG. 3, micro LED structure 310 includes a mesa structure 311 and a bottom connect structure 312. Bottom connect structure 312 is provided at a bottom of mesa structure 311 to electrically connect mesa structure 311 with a bottom pad 321 of integrated circuit (IC) backplane 320. In some embodiments, bottom connect structure 312 is a Cu-pad. IC backplane 320 is provided at a bottom of micro LED array 301 for providing control of micro LED array 301.

Micro LED structure 310 further includes a first thermal conductive layer 313 formed surrounding a sidewall of mesa structure 311 and a second thermal conductive layer 314 filled between adjacent ones of micro LED structures 310.

Referring to FIG. 3, micro LED array 301 further includes a first bonding layer 318 provided at a bottom of micro LED array 301. IC backplane 320 includes a second bonding layer 324 and a substrate layer 323, second bonding layer 324 is provided on a top of substrate layer 323. First bonding layer 318 and second bonding layer 324 are bonded. The bonding layer 318 and 324 may be SiO2, SiN, SiONx, AlN, Boron Nitride, SiC, diamond, diamond-like carbon or a combination thereof. The bonding procedure may be accomplished using a covalent bonding process.

In some embodiments, a material of first bonding layer 318 and second bonding layer 324 is an electrically insulative material with high thermal conductivity. In some embodiments, a thermal conductivity of the electrically insulative material of first bonding layer 318 and second bonding layer 324 is greater than 300 W/mK. For example, the material of first bonding layer 318 and second bonding layer 324 is AlN, SiC, Boron, Nitride, diamond, diamond-like carbon, and the like. It can be understood that a material of the first bonding layer and a material of the second bonding layer can be the same or different. In some embodiments, the material of first bonding layer 318 is the same as the material of second thermal conductive layer 314.

IC backplane 320 includes one or more heat dissipation structures 322 provided corresponding to an area outside micro LED structure 310 and passing thought IC backplane 320 to radiate heat to outside, shown as an arrow 350 in FIG. 3. Heat dissipation structure 322 and bottom pad 321 are separated. In this example, as shown in FIG. 3, heat dissipation structure 322 passes through substrate layer 323 and is in contact with second bonding layer 324 to radiate heat from second bonding layer 324.

In some embodiments, mesa structure 311 includes a P-N structure. For example, mesa structure 311 includes a first semiconductor layer 311A, a second semiconductor layer 311C, and a light emitting layer 311B provided between first semiconductor layer 311A and second semiconductor layer 311C. Light emitting layer 311B can emit red light, green light, or blue light. In some embodiments, an area of a top surface of mesa structure 311 is greater than an area of bottom surface of mesa structure 311. In some embodiments, an area of a top surface of mesa structure 311 is smaller than an area of bottom surface of mesa structure 311. In some embodiments, first semiconductor layer 311A is an N-type semiconductor layer, and second semiconductor layer 311C is a P-type semiconductor layer. Micro LED array 301 further includes a second N-type semiconductor layer 316 formed on a top of micro LED array 301, so that a continuous N-type semiconductor layer is provided and can electrically connect respective N-type semiconductor layers of mesa structures 311.

In some embodiments, micro LED array 301 further includes a top conductive layer 317 provided on second N-type semiconductor layer 316. In some embodiments, top conductive layer 317 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, as shown in FIG. 3, micro LED structure 310 further includes a reflective layer 315 provided on the sidewall of mesa structure 311 and a bottom surface of mesa structure 311. First thermal conductive layer 313 is provided between the sidewall of mesa structure 311 and reflective layer 315. Reflective layer 315 can reflect light emitted by mesa structure 311 upwards, thereby improving the light emission efficiency and reducing light crosstalk between adjacent ones of micro LED structures. In some embodiments, reflective layer 315 is a mirror layer.

Referring to FIG. 3, in some embodiments, micro LED structure 310 further includes a bottom conductive layer 319 provided between mesa structure 311 and bottom connect structure 312 to provide an ohmic contact between mesa structure 311 and bottom connect structure 312. First thermal conductive layer 313 is further formed surrounding a sidewall of bottom conductive layer 319. In some embodiments, bottom conductive layer 319 includes an omni-directional reflector (ODR) structure with high reflectivity. In some embodiments, bottom conductive layer 319 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, bottom conductive layer 319 is provided between mesa structure 311 and reflective layer 315 to provide an ohmic contact between mesa structure 311 and reflective layer 315. Therefore, a bottom of mesa structure 311 is electrically connected with bottom connect structure 312 through bottom conductive layer 319 and reflective layer 315.

Description of other features of micro LED display panel 300 may be found by referring to such features described above with reference to FIG. 1, which will not be repeated here.

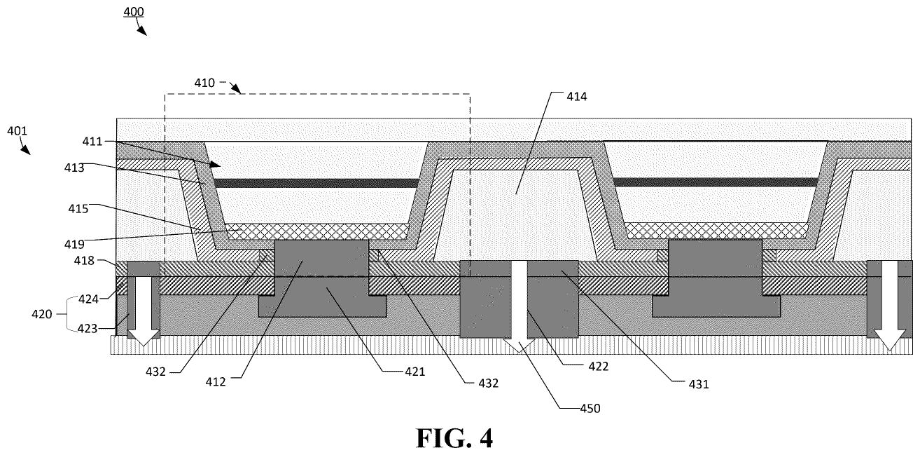

FIG. 4 illustrates a structural cross-sectional diagram of another exemplary micro LED display panel 400, according to some embodiments of the present disclosure. Micro LED display panel 400 includes a micro LED array 401 and an IC (integrated circuit) backplane 420. Micro LED array 401 is located on IC backplane 420 to form an image display area of micro LED display panel 400. Micro LED array 401 includes a plurality of micro LED structures 410. Micro LED structure 410 includes a mesa structure 411 and a bottom connect structure 412. Bottom connect structure 412 is provided at a bottom of mesa structure 411 to connect mesa structure 411 with a bottom pad 421 of IC backplane 420. Micro LED array 401 further includes a reflective layer 415 provided on the sidewall of mesa structure 411 and a bottom surface of mesa structure 411. A first thermal conductive layer 413 is provided between the sidewall of mesa structure 411 and reflective layer 415. Bottom connect structure 412 passes through reflective layer 415, and bottom connect structure 412 passes through first thermal conductive layer 413 and reflective layer 415 to connect the bottom of mesa structure 411. Micro LED structure 401 further includes an isolation ring 432 provided between bottom connect structure 412 and reflective layer 415 to isolate bottom connect structure 412 from reflective layer 415. It can be understood that in some embodiments, isolation ring 432 is provided around bottom connect structure 412. In some embodiments, a material of the isolation ring 432 is a dielectric material, for example, SiO₂.

In some embodiments, micro LED structure 410 further includes a bottom conductive layer 419 provided at a bottom of mesa structure 411. Bottom connect structure 412 passes through first thermal conductive layer 413 and reflective layer 415 to connect to bottom conductive layer 419. Bottom conductive layer 419 can provide an ohmic contact between mesa structure 411 and bottom connect structure 412. In some embodiments, bottom conductive layer 419 includes an omni-directional reflector (ODR) structure with high reflectivity. In some embodiments, bottom conductive layer 419 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

As shown in FIG. 4, micro LED array 401 further includes a second thermal conductive layer 414 filled between adjacent ones of micro LED structures 410. In this example, first thermal conductive layer 413 is further formed over a top surface of the second thermal conductive layer 414, and reflective layer 415 is further provided between first thermal conductive layer 413 and second thermal conductive layer 414.

As shown in FIG. 4, micro LED array 401 further includes a first bonding layer 418 provided at a bottom of micro LED array 401. IC backplane 420 includes a second bonding layer 424 and a substrate layer 423. Second bonding layer 424 is provided on a top of substrate layer 423. First bonding layer 418 and second bonding layer 424 are bonded. In this example, a material of first bonding layer 418 and second bonding layer 424 is a dielectric layer. For example, the material of first bonding layer 418 and second bonding layer 424 is SiO₂, SiN, or SiCN. It can be understood that a material of the first bonding layer and a material of the second bonding layer can be the same or different. In some embodiments, the material of second bonding layer 424 is the same as the material of substrate layer 423.

Referring to FIG. 4, IC backplane 420 includes one or more heat dissipation structures 422 provided corresponding to an area outside micro LED structure 410 and passing thought IC backplane 420 to radiate heat to outside, shown as an arrow 450 in FIG. 4 Heat dissipation structure 422 and bottom pad 421 are separated. In this example, as shown in FIG. 4, heat dissipation structure 422 passes through second bonding layer 424 and substrate layer 423. First bonding layer 418 further includes a plurality of second heat dissipation structures 431 corresponding to the one or more heat dissipation structures 422. Therefore, heat can be radiated through second heat dissipation structures 431 and heat dissipation structures 422 from second thermal conductive layer 414 to outside. In some embodiments, a material of second dissipation structure 431 is a metal. In some embodiments, a material of second dissipation structure 431 and a material of heat dissipation structure 422 are the same. For example, second heat dissipation structure 431 is a Cu pad.

Description of other features of micro LED display panel 400 may be found by referring to such features described above with reference to FIG. 3, which will not be repeated here.

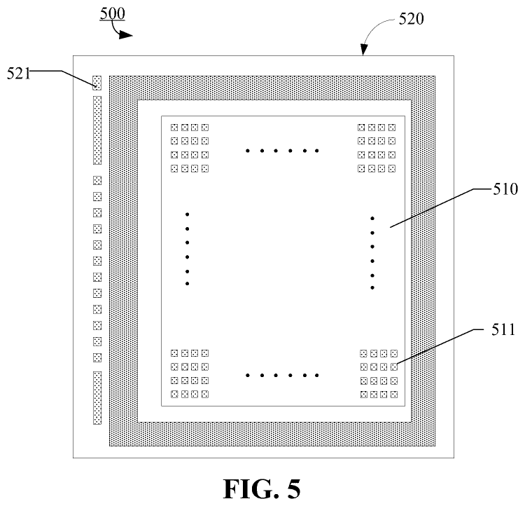

FIG. 5 illustrates a structural diagram showing a top view of a micro LED display panel 500, according to some embodiments of the present disclosure. Referring to FIG. 5, micro LED display panel 500 includes a micro LED array 510 (for example, micro LED array 101, micro LED array 201, micro LED array 301, or micro LED array 401) and an IC (integrated circuit) backplane 520. Micro LED array 510 is located on IC backplane 520 to form an image display area of micro LED display panel 500. The rest of the area on IC backplane 520 not covered by micro LED array 510 is formed as a non-functional area. IC backplane 520 is formed at the back surface of micro LED array 510 with a part extending outside of, i.e., not covered by, micro LED array 410. Micro LED array 510 includes a plurality of micro LEDs 511 (for example, micro LED structure 110, micro LED structure 210, micro LED structure 310, or micro LED structure 410) provided micro LED array 510. IC backplane 520 is configured to control the plurality of micro LEDs 511. IC backplane 520 may include a bottom pad array (not shown) corresponding to micro LED array 510. The bottom pad array includes a plurality of bottom pads (for example, bottom pad 121, bottom pad 221, bottom pad 321, or bottom pad 421), and one bottom pad corresponds to one micro LED 511. One micro LED of the plurality of micro LEDs is electrically connected with one bottom pad of the plurality of the bottom pad.

In some embodiments, a top conductive layer (for example, top conductive layer 117 or top conductive layer 317) of the micro LED is interconnected with each of the plurality of micro LEDs. That is, the top conductive layer is continuously formed on a top of micro LED array 510, and connected with every micro LED 511.

In some embodiments, IC backplane 520 further includes a top connected pad 521. The top conductive layer is connected with top connected pad 521, and further may connect to an external circuit.

Each micro LED structure herein (e.g., micro LED structure 110, micro LED structure 210, micro LED structure 310, micro LED structure 410) has a very small volume. The micro LED structure can be applied in a micro LED display panel. The light emitting area of the micro LED display panel, e.g., micro LED display panel 500, is very small, such as 1 mm×1 mm, 3 mm×5 mm, etc. In some embodiments, the light emitting area is the area of micro LED array 510 in the micro LED display panel 500. The micro LED display panel includes one or more micro LEDs that form a pixel array in which the micro LEDs of micro LED array 510 are pixels, such as a 1600×1200, 680×480, or 1920×1080-pixel array. The diameter of each micro LED is in the range of about 200 nm to 2 μm. An IC backplane, e.g., IC backplane 520, is formed at the back surface of micro LED array 510 and is electrically connected with micro LED array 510. IC backplane 520 acquires signals such as image data from outside via signal lines to control corresponding micro LEDs 511 to emit light or not.

It is understood by those skilled in the art that the micro LED display panel is not limited by the structure described above, and may include greater or fewer components than those illustrated, or some components may be combined, or a different component may be utilized.

The embodiments may further be described using the following clauses:
1. A micro LED display panel, comprising:
an integrated circuit (IC) backplane comprising a bottom pad array, the bottom pad array comprising a plurality of bottom pads; and
a micro LED array comprising a plurality of micro LED structures provided on the IC backplane, one micro LED structure of the plurality of micro LED structures being electrically connected with one bottom pad of the plurality of bottom pads;
each of the micro LED structures comprising:
   a mesa structure;
   a first thermal conductive layer formed surrounding a sidewall of the mesa structure, a material of the first thermal conductive layer being an electrically insulative material with high thermal conductivity; and
   a second thermal conductive layer filled between adjacent ones of micro LED structures, a material of the second thermal conductive layer being a material with high thermal conductivity; and
   the IC backplane further comprising:
   one or more heat dissipation structures corresponding to an area outside the micro LED structure and passing thought the IC backplane to radiate heat to outside, wherein the heat dissipation structure and the bottom pad are separated.
2. The micro LED display panel according to clause 1, wherein the one or more heat dissipation structures are provided corresponding to areas between adjacent ones of micro LED structures.
3. The micro LED display panel according to clause 1, wherein a thermal conductivity of the electrically insulative material of the first thermal conductive layer is greater than 300 W/mK.
4. The micro LED display panel according to clause 3, wherein the material of the first thermal conductive layer is AlN, SiC, Boron, Nitride, diamond, or diamond-like carbon.
5. The micro LED display panel according to clause 1, wherein a thermal conductivity of the material of the second thermal conductive layer is greater than 300 W/mK.
6. The micro LED display panel according to clause 5, wherein the material of the second thermal conductive layer is electrically insulative.
7. The micro LED display panel according to clause 6, wherein the material of the second thermal conductive layer is AlN, SiC, Boron, Nitride, diamond, or diamond-like carbon.
8. The micro LED display panel according to clause 5, wherein the material of the second thermal conductive layer is electrically conductive.
9. The micro LED display panel according to clause 8, wherein the material of the second thermal conductive layer is Ag, Cu, Al, Graphite, or Graphene.
10. The micro LED display panel according to any one of clauses 1 to 9, wherein the heat dissipation structure is in contact with the second thermal conductive layer.
11. The micro LED display panel according to any one of clauses 1 to 9, wherein the first thermal conductive layer is further provided on a top surface of the IC backplane between the adjacent ones of micro LED structures, and the heat dissipation structure is in contact with the first thermal conductive layer.
12. The micro LED display panel according to clause 9, wherein the micro LED array further comprises a first bonding layer provided at a bottom of the micro LED array; and
the IC backplane comprises a second bonding layer and a substrate layer, the second bonding layer provided at a top of the substrate layer; wherein the first bonding layer and the second bonding layer are bonded.
13. The micro LED display panel according to clause 12, wherein a material of the first bonding layer and the second bonding layer is an electrically insulative material with high thermal conductivity.
14. The micro LED display panel according to clause 13, wherein a thermal conductivity of the electrically insulative material of the first bonding layer and the second bonding layer is greater than 300 W/mK.
15. The micro LED display panel according to clause 14, wherein the electrically insulative material of the first bonding layer and the second bonding layer is AlN, SiC, Boron, Nitride, diamond, or diamond-like carbon.
16. The micro LED display panel according to clause 13, wherein the heat dissipation structure passes through the substrate layer in a vertical direction and in contact with the second bonding layer.
17. The micro LED display panel according to clause 12, wherein a material of the first bonding layer and the second bonding layer is dielectric.
18. The micro LED display panel according to clause 17, wherein the material of the first bonding layer and the second bonding layer is SiO₂, SiN, or SiCN.
19. The micro LED display panel according to clause 17, wherein the heat dissipation structure is a first heat dissipation structure that passes through the second bonding layer and the substrate layer, and the first bonding layer comprises a plurality of second heat dissipation structures corresponding to the plurality of heat dissipation structure.
20. The micro LED display panel according to any one of clauses 1 to 9, wherein a material of the heat dissipation structure is a metal.
21. The micro LED display panel according to clause 20, wherein the heat dissipation structure is a Cu pad.
22. An integrated circuit (IC) backplane, comprising:
a plurality of bottom pads, one bottom pad of the plurality of bottom pads being electrically connected with one micro LED structure of a plurality of micro LED structures; and
one or more heat dissipation structures provided corresponding to an area outside the micro LED structure and passing thought the IC backplane to radiate heat to outside, wherein the heat dissipation structure and the bottom pad are separated.
23. The IC backplane according to clause 22, wherein the one or more heat dissipation structures are provided corresponding to areas between adjacent ones of micro LED structures.
24. The IC backplane according to clause 22, comprising a bonding layer and a substrate layer, the bonding layer being provided on the substrate layer.
25. The IC backplane according to clause 24, wherein a material of the bonding layer is an electrically insulative material with high thermal conductivity, and the heat dissipation structure passes through the substrate layer and in contact with the bonding layer.
26. The IC backplane according to clause 24, wherein a material of the bonding layer is dielectric, and the heat dissipation structure passes through the bonding layer and the substrate layer.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
an integrated circuit (IC) backplane comprising a bottom pad array, the bottom pad array comprising a plurality of bottom pads; and
a micro LED array comprising a plurality of micro LED structures provided on the IC backplane, one micro LED structure of the plurality of micro LED structures being electrically connected with one bottom pad of the plurality of bottom pads;
each of the micro LED structures comprising:
a mesa structure;
a first thermal conductive layer formed surrounding a sidewall of the mesa structure, a material of the first thermal conductive layer being an electrically insulative material with high thermal conductivity; and
a second thermal conductive layer filled between adjacent ones of micro LED structures, a material of the second thermal conductive layer being a material with high thermal conductivity; and
the IC backplane further comprising:
one or more heat dissipation structures corresponding to an area outside the micro LED structure and passing thought the IC backplane to radiate heat to outside, wherein the heat dissipation structure and the bottom pad are separated.

2. The micro LED display panel according to claim 1, wherein the one or more heat dissipation structures are provided corresponding to areas between adjacent ones of micro LED structures.

3. The micro LED display panel according to claim 1, wherein a thermal conductivity of the electrically insulative material of the first thermal conductive layer is greater than 300 W/mK.

4. The micro LED display panel according to claim 3, wherein the material of the first thermal conductive layer is AlN, SiC, Boron, Nitride, diamond, or diamond-like carbon.

5. The micro LED display panel according to claim 1, wherein a thermal conductivity of the material of the second thermal conductive layer is greater than 300 W/mK.

6. The micro LED display panel according to claim 5, wherein the material of the second thermal conductive layer is electrically insulative.

7. The micro LED display panel according to claim 6, wherein the material of the second thermal conductive layer is AlN, SiC, Boron, Nitride, diamond, or diamond-like carbon.

8. The micro LED display panel according to claim 5, wherein the material of the second thermal conductive layer is electrically conductive.

9. The micro LED display panel according to claim 8, wherein the material of the second thermal conductive layer is Ag, Cu, Al, Graphite, or Graphene.

10. The micro LED display panel according to claim 1, wherein the heat dissipation structure is in contact with the second thermal conductive layer.

11. The micro LED display panel according to claim 1, wherein the first thermal conductive layer is further provided on a top surface of the IC backplane between the adjacent ones of micro LED structures, and the heat dissipation structure is in contact with the first thermal conductive layer.

12. The micro LED display panel according to claim 9, wherein the micro LED array further comprises a first bonding layer provided at a bottom of the micro LED array; and
the IC backplane comprises a second bonding layer and a substrate layer, the second bonding layer provided at a top of the substrate layer; wherein the first bonding layer and the second bonding layer are bonded.

13. The micro LED display panel according to claim 12, wherein a material of the first bonding layer and the second bonding layer is an electrically insulative material with high thermal conductivity.

14. The micro LED display panel according to claim 13, wherein a thermal conductivity of the electrically insulative material of the first bonding layer and the second bonding layer is greater than 300 W/mK.

15. The micro LED display panel according to claim 14, wherein the electrically insulative material of the first bonding layer and the second bonding layer is AlN, SiC, Boron, Nitride, diamond, or diamond-like carbon.

16. The micro LED display panel according to claim 13, wherein the heat dissipation structure passes through the substrate layer in a vertical direction and in contact with the second bonding layer.

17. The micro LED display panel according to claim 12, wherein a material of the first bonding layer and the second bonding layer is dielectric.

18. The micro LED display panel according to claim 17, wherein the material of the first bonding layer and the second bonding layer is SiO₂, SiN, or SiCN.

19. The micro LED display panel according to claim 17, wherein the heat dissipation structure is a first heat dissipation structure that passes through the second bonding layer and the substrate layer, and the first bonding layer comprises a plurality of second heat dissipation structures corresponding to the plurality of heat dissipation structure.

20. The micro LED display panel according to claim 1, wherein a material of the heat dissipation structure is a metal.

21. The micro LED display panel according to claim 20, wherein the heat dissipation structure is a Cu pad.

22. An integrated circuit (IC) backplane, comprising:
a plurality of bottom pads, one bottom pad of the plurality of bottom pads being electrically connected with one micro LED structure of a plurality of micro LED structures; and
one or more heat dissipation structures provided corresponding to an area outside the micro LED structure and passing thought the IC backplane to radiate heat to outside, wherein the heat dissipation structure and the bottom pad are separated.

23. The IC backplane according to claim 22, wherein the one or more heat dissipation structures are provided corresponding to areas between adjacent ones of micro LED structures.

24. The IC backplane according to claim 22, comprising a bonding layer and a substrate layer, the bonding layer being provided on the substrate layer.

25. The IC backplane according to claim 24, wherein a material of the bonding layer is an electrically insulative material with high thermal conductivity, and the heat dissipation structure passes through the substrate layer and in contact with the bonding layer.

26. The IC backplane according to claim 24, wherein a material of the bonding layer is dielectric, and the heat dissipation structure passes through the bonding layer and the substrate layer.
